(19) United States
(12) Patent Application Publication
(10) Pub. No.: US 2007/0197030 A1
(43) Pub. Date: Aug. 23, 2007

(54) CENTER PAD TYPE IC CHIP WITH JUMPERS, METHOD OF PROCESSING THE SAME AND MULTI CHIP PACKAGE

(75) Inventors: Gu-Sung KIM, Kyungki-do, (KR); Dong-Hyeon JANG, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/739,582

(22) Filed: Apr. 24, 2007

Related U.S. Application Data
(62) Division of application No. 10/269,328, filed on Oct. 10, 2002, now Pat. No. 7,224,055.

(51) Int. Cl. H01L 21/44

(52) U.S. Cl. 438/674; 438/669

(57) ABSTRACT

A center pad type integrated circuit chip and a method of forming the same is presented. The chip comprises an integrated circuit chip having chip pads formed on a center region thereof and a jumper. The jumper includes a buffer layer arranged adjacent to a side of the chip pads and a plurality of jump metal lines formed on the buffer layer. The jump metal lines are spaced apart from each other.

### CROSS REFERENCE TO RELATED APPLICATIONS

This application is a divisional of U.S. patent application Ser. No. 10/269,328, filed Oct. 10, 2002, now pending, which is claims priority from Korean Patent Application No. 2001-72348, filed on Nov. 20, 2001, the disclosure of which are incorporated herein in its entirety by reference.

### TECHNICAL FIELD OF THE INVENTION

The present invention relates to a semiconductor device and, more particularly, to a center pad type integrated circuit (IC) chip, a method of manufacturing the same, and a multi chip package.

### BACKGROUND OF THE INVENTION

Recent trends in electronics have been towards miniaturization, reduced weight, and multifunctionality. In order to satisfy these pressing demands, multi chip packaging technology has been developed. The technology incorporates a plurality of IC chips of the same type or different type in a single package. The multi chip packaging technology is advantageous in terms of size, weight and mounting density as compared to the case where only one IC chip is mounted in the single package so that a plurality of packages is required for mounting the plurality of IC chips. In the conventional multi chip packaging technology, two IC chips of same type or different type are attached to the board in turn, and IC chips and the board are electrically connected using a wire-bonding method. The conventional multi chip packaging technology will be described below with reference to FIGS. 1 to 3.

FIG. 1 is a plan view of a package before encapsulation in accordance with one example of a conventional multi chip package; FIG. 2 is a cross sectional view taken along line 2-2 of FIG. 1; FIG. 3 is a cross sectional view taken along line 3-3 of FIG. 1.

As shown in FIGS. 1 through 3, the conventional multi chip package 110 includes a first IC chip 111 having chip pads 112 along two edges of the chip and a second IC chip 113 having a row of chip pads 114 along the center of the chip. The first chip 111 is attached to the board 121 with an adhesive 151 and the second chip 113 is attached to the first chip 111 with an adhesive 153. The active surfaces of chips 111 and 113, on which the integrated circuits are formed, face the same direction. The first chip 111 and second chip 113 are electrically connected to the board 121 by wire-bonding chip pads 112 and 114 to the corresponding board pads 123 using bonding wires 141 and 143. Since the chip pads 114 of the second chip 113 are far from the board pads 123, the bonding wires 143 of the second chip 113 have long loops. As a result, problems such as cutting, sagging, and short-circuit of the bonding wires 143 are prevalent.

As an alternative method for solving the above problems, pad redistribution methods or the use of special bonding wires has been proposed. With the pad redistribution method, the chip pads of the second chip 113 are moved from the center to the edge of the chip. However, because this method requires many additional processes to form several more layers on the chip, the processing cost and time increase. Furthermore, the density of devices on the chip decreases because the pad redistribution method requires separate processes based on the IC chip and wafer sizes. For example, in the case where special gold (Au) bonding wires coated with a polymer material is used, the cost of the bonding wires is much more expensive and the manufacturing cost of the package is greatly increased.

As another alternative, a method used in ceramic packaging can be adopted. That is, a separate IC chip or jumper chip is attached to the board around the second chip. More specifically, by wire bonding the second chip to the jumper chip and then wire bonding the jumper chip to the board, the bonding wires of the second chip no longer have long fragile loops. However, because the number of jumper chips required is equal to the number of bonding wires, there are many drawbacks in terms of size, weight and manufacturing cost.

### SUMMARY OF THE INVENTION

Accordingly, the present invention provides a center pad type IC chip having a jumper, a method of manufacturing the same, and a multi chip package capable of solving problems caused by long loops of bonding wires without many additional processes and greatly increasing the manufacturing cost.

A center pad type integrated circuit chip comprises an integrated circuit chip having chip pads formed on a center region thereof and a jumper. The jumper includes a buffer layer arranged adjacent to a side of the chip pads and a plurality of jump metal lines formed on the buffer layer. The jump metal lines are spaced apart from each other.

With the descriptions mentioned above along with other feature and advantages, the outline will be more clearly understood from the following detailed description taken in conjunction with the accompanying illustrations. It is important to point out that the illustrations may not necessarily be drawn to scale and there may be other embodiments to this invention that are not specifically illustrated.

### BRIEF DESCRIPTION OF THE DRAWINGS

These and other objects, features and advantages of the present invention will be readily understood with reference to the following detailed description thereof provided in conjunction with the accompanying drawings, wherein like reference numerals designate like structural elements, and, in which:

FIG. 1 is a plan view of the package before encapsulation in accordance with one example of the conventional multi chip package;

FIG. 2 is a cross sectional view taken along line 2-2 of FIG. 1;

FIG. 3 is a cross sectional view taken along line 3-3 of FIG. 1;

FIG. 4 is a plan view of the multi chip package before encapsulation in accordance with an embodiment of the present invention;

FIG. 5 is a cross sectional view taken along line 6-6 of FIG. 4;

FIG. 6 is a cross sectional view taken along line 5-5 of FIG. 4;

FIGS. 7A to 7D illustrates the sputtering method employed in manufacturing a center pad type IC chip in accordance with an embodiment of the present invention;

FIGS. 8A and 8B illustrates the laser-milling method employed in manufacturing a center pad type IC chip in accordance with an embodiment of the present invention;

FIG. 9 is a cross sectional view of a jumper tape used in the present invention; and

FIG. 10 is a cross sectional view of a multi chip package according to another embodiment of the present invention, in which the jumper tape of FIG. 9 is employed.

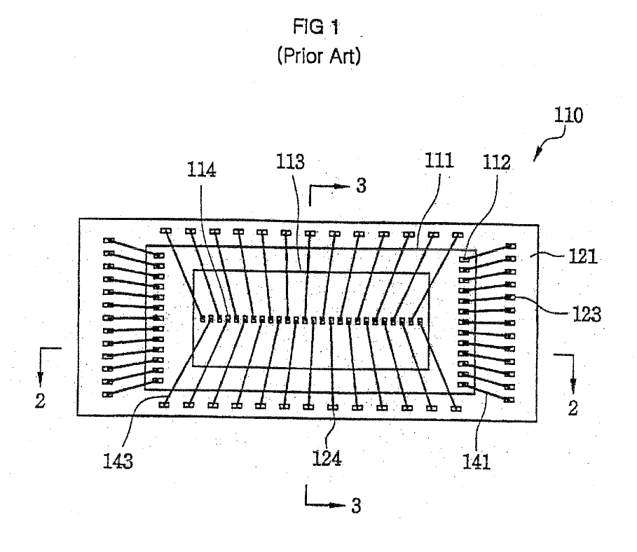

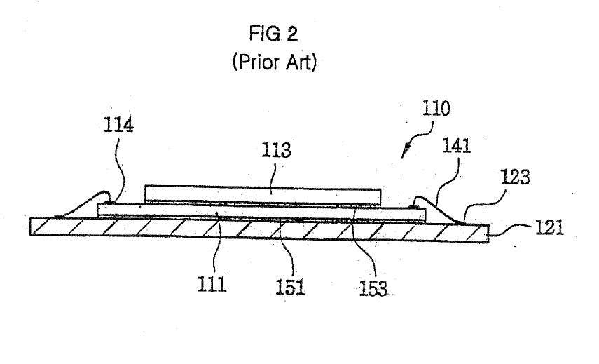

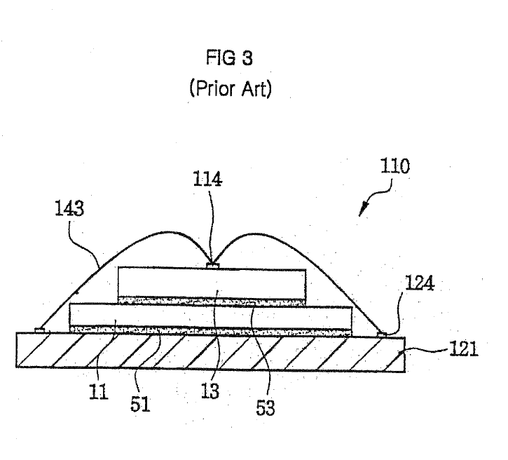

### DETAILED DESCRIPTION OF PREFERRED EMBODIMENTS

Preferred embodiments of the invention will be described below with reference to the accompanying drawings.

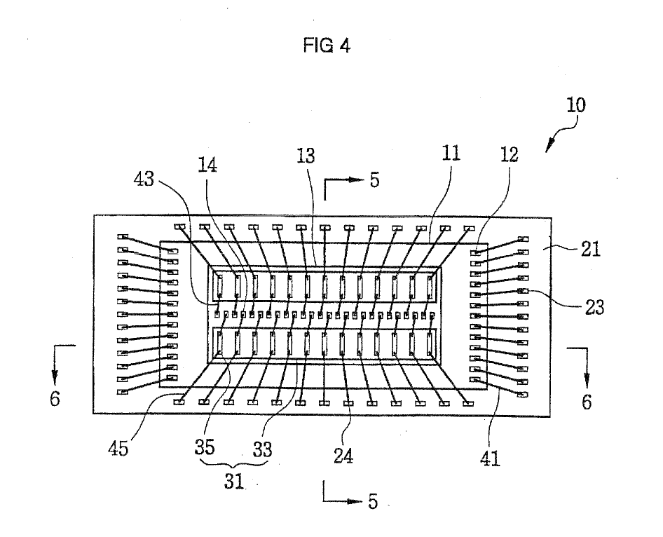

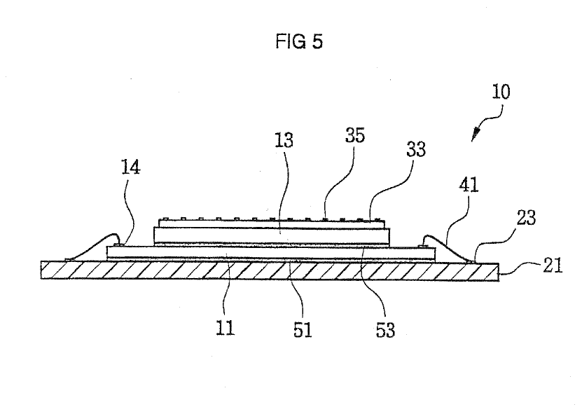

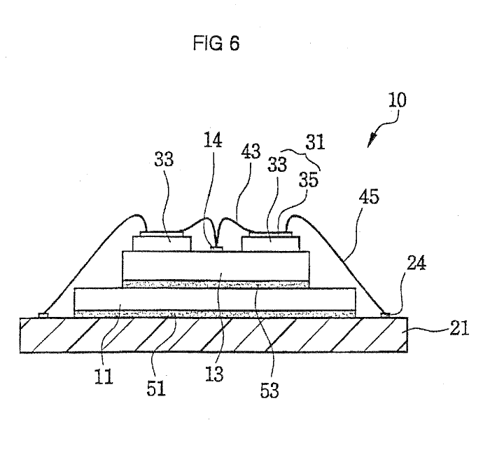

FIG. 4 is a plan view of a multi chip package before encapsulation in accordance with an embodiment of the present invention; FIG. 5 is a cross sectional view taken along line 6-6 of FIG. 4; FIG. 6 is a cross sectional view taken along line 5-5 of FIG. 4.

Referring to FIGS. 4 through 6, the multi chip package 100 in accordance with an embodiment of the present invention includes a first IC chip 11, a second IC chip 13 and a board 21 for mounting the chips 11, 13. The board 21 has a chip mounting area substantially at the center and board pads 23 at four edges. A tape circuit board or a printed circuit board may be used for the board 21.

The first chip 11 is attached to the chip mounting area with an adhesive 51. The first chip 11 is an edge pad type in which chip pads 12 are formed on opposites sides of the active surface thereof. Integrated circuits are formed in the active surface. The surface opposite the active surface of the first chip 11 is a non-active surface used for attachment to the board 21.

The second chip 13 is attached to the first chip 11 with an adhesive 53. The second chip 13 is a center pad type in which chip pads 14 are formed substantially at the center of the active surface. The second chip 13 is smaller than the first chip 11. The chip pads 14 of the second chip 13 are arranged perpendicularly to the rows of the chip pads of the first chip 11. The second chip 13 can have various sizes and shapes as long as the chip pads 12 of the first chip 11 are exposed. The non-active surface of the second chip 13 is used for attachment to the first chip 11.

Jumpers 31 are formed at both edges of the chip pads 14 of the second chip 13. The jumpers 31 have a buffer layer 33 on the active surface and jump metal lines 35 on the buffer layer 33. The buffer layer 33 is made of an insulation material such as polyimide. The jump metal lines 35 have a predetermined pitch and pattern so that one side of the jump metal line 35 is adjacent the chip pads 14 at the center of the second chip 13 and other side is adjacent to edge of the second chip 13. The jump metal line 35 comprises a metal having excellent electric conductivity, such as gold (Au), aluminum (Al), or palladium (Pd).

The first chip 11 is directly connected to the board 21 via bonding wires, while the second chip 13 is indirectly connected to the board 21 via bonding wires attached to the jumpers 31. Specifically, the first chip 11 is electrically connected to the board 21 by wire-bonding the chip pads 12 of the first chip 11 to the corresponding board pads 23 via first bonding wires 41. The second chip 13 is electrically connected to the board 21 by the following process. That is, the chip pads 14 of the second chip 13 are wire-bonded to the corresponding sides of jump metal lines 35 adjacent the chip pads 14 via second bonding wires 43, and then the other sides of jump metal lines 35 adjacent the edge of the second chip 13 are wire-bonded to the corresponding board pads 23 via jump bonding wires 45.

The multi chip package of an embodiment of the present invention can be a BGA (ball grid array) package having solder balls as external connections, or a TCP (tape carrier package).

As described above, the problems caused by long loops can be solved by including the jumper in the multi chip package according to an embodiment of the present invention. Although the jump metal lines of the jumper have a predetermined pitch and pattern in this embodiment, the pitch and pattern of the jump metal line may be changed, if necessary. Furthermore, the jumper can be formed at the chip or wafer level. Hereinafter, the jumper will be described.

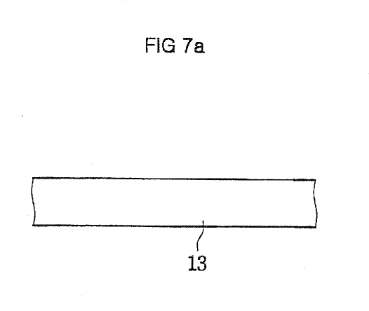

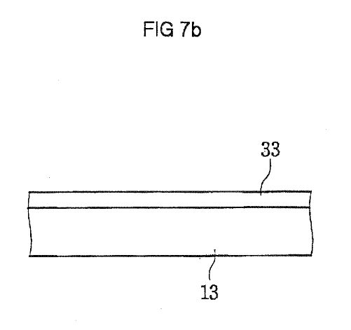

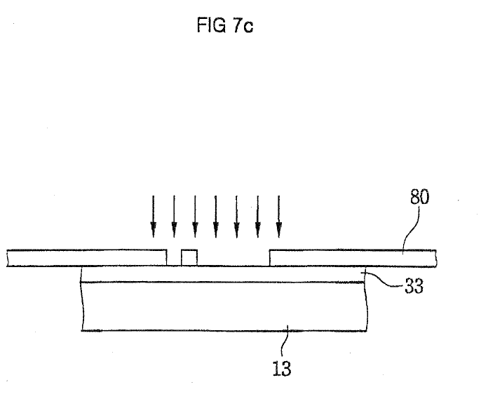

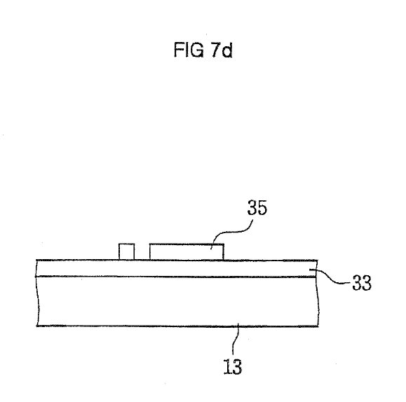

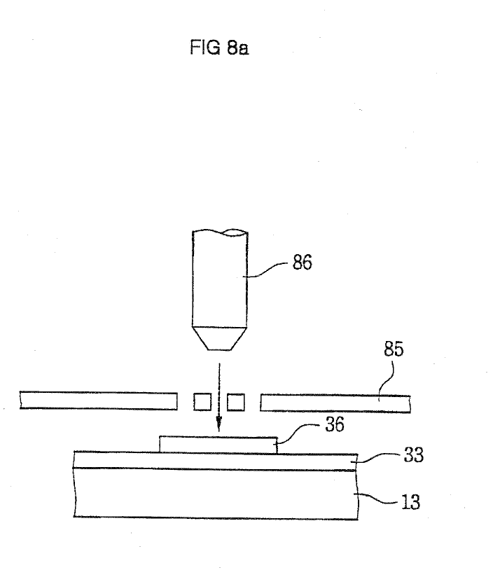

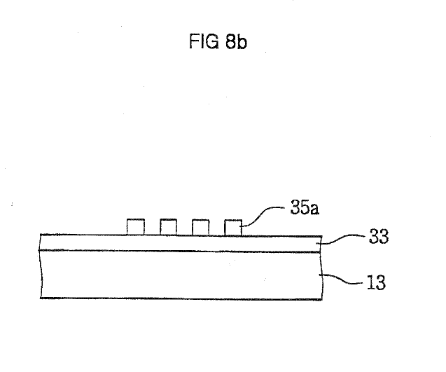

First, jumpers formed at the wafer level are described below in reference to FIGS. 7 and 8.

FIGS. 7A to 7D illustrate a sputtering process used in the manufacture of the center pad type IC chip in accordance with an embodiment of the present invention. FIGS. 8A and 8B illustrate a laser-milling process used in the manufacture of the center pad type IC chip in accordance with another embodiment of the present invention.

As illustrated in FIG. 7A, the center pad type chip 13, in which the ICs are formed in the active surface, is fabricated in the wafer level. Then, as illustrated in FIG. 7B, the buffer layer 33 made of an insulating material such as polyimide is formed on the active surface of chip 13 adjacent sides of the chip pads 14 of chip 13. As illustrated in FIG. 7C, a mask 80 is arranged on the buffer layer 33 and then a sputtering process is carried out thereon. The mask 80 is composed of a metal such as SUS or Molybdenum (MO). The jump metal lines 35 are formed as illustrated in FIG. 7D.

As described above, a center pad type chip with jumpers in accordance with an embodiment of the present invention can be simply manufactured by aligning the mask and then sputtering to form the metal lines, without the need for several photolithography processes. In the case of using a mask as described above, a bridge connecting the adjacent metal lines can be generated due to an extremely small space between the mask aligned on the chip and the active surface of the chip. The bridge can later be removed with an ion milling or ion etching process.

Alternatively, as illustrated in FIG. 8A, after forming the buffer layer 33 on the chip 13, a metal layer 36 is formed on the buffer layer 33. Next, a glass mask 85 is aligned on the metal layer 36 and then a milling process is carried out using a laser device. Then, as illustrated in FIG. 8B, jump metal lines 35a are obtained that are denser than jump metal lines 35 of FIG. 7D.

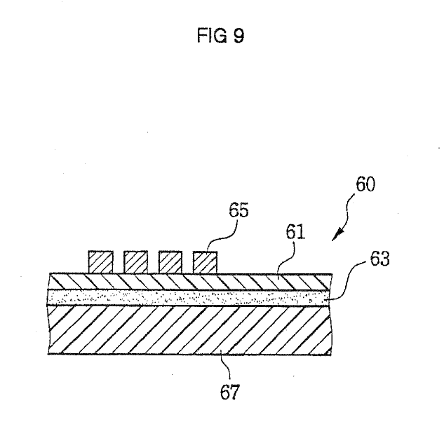

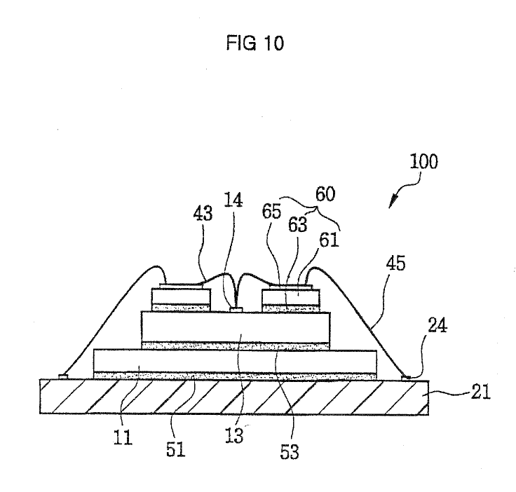

Next, a jumper formed at the chip state will be described below in reference to FIGS. 9 and 10.

FIG. 9 is a cross sectional view of a jumper tape used as the jumper in the present invention. FIG. 10 is a cross sectional view of a multi chip package in accordance with another embodiment of the present invention, in which the jumper tape of FIG. 9 is employed as the jumper.

As illustrated in FIG. 9, a jumper tape 60 includes a base film 61, jump metal lines 65 on the base film 61 and an adhesive layer 63 for easily attaching the chip. The jump metal lines 65 are formed on one surface of the base film 61 by an electroplating or vapor deposition process of additive or semi additive type. The adhesive layer 63 is formed on the other surface of the base film 61. An adhesive or thermosetting resin can be used as the adhesive layer 63. A cover film 67 for easy handling may be attached to the other surface of the base film 61, opposite the surface on which the metal lines 65 are formed. As a simpler method, the jump metal line 65 can be formed by punching or stamping processes after forming metal layers, or by the bulk etching of thin film. Accordingly, the jump metal lines 65 can be mass-produced at low cost.

The problems caused by the long loop can be solved by attaching the jumper tape as shown in FIG. 9 to the center pad type chip using the conventional method of manufacturing the multi chip package. In other words, separate processes for forming the jumpers are not needed.

As shown in FIG. 10, in the multi chip package 100 with the jumper tape 60 of FIG. 9 forming the jumper, the jumper tape 60 is formed on the center pad type chip 13. The jump metal lines 65 are formed on one surface of the base film 61 of the jumper tape 60, and the adhesive layer 63 is formed on the other surface of the base film 61, opposite the surface on which the jump metal lines 65 are formed.

Since the jumper tape 60 is manufactured in a roll shape, the productivity increases and the manufacturing cost decreases. Furthermore, one type of jumper tape can be used for several types of chips regardless of the chip type, as long as the jump metal lines are disposed at the edge of the chip pads.

According to the present invention, since the bonding wires do not possess a long loop, the cutting, sagging, and short-circuiting of the bonding wires is prevented. Furthermore, since the jumpers are easily manufactured by aligning the mask and then sputtering without the complicated redistribution processes, the manufacturing cost is decreased. Since denser jump metal lines are easily formed by laser milling, the multi-photolithography etching process can be omitted. Moreover, since the jumpers are manufactured in a roll-tape shape, productivity increases while the manufacturing cost decreases. Furthermore, one type of jumper tape can be used in several types of chips regardless of the chip type.

The drawings and specification have disclosed typical preferred embodiments of present invention. Although specific terms are employed, they are used in a generic and descriptive sense only and not for purposes of limitation, the scope of this invention being set forth in the following claims.

What is claimed is:

1. A method of manufacturing an integrated circuit chip having chip pads formed on a center region thereof, the method comprising:
forming a buffer layer on the chip, the buffer layer arranged adjacent to a side of the chip pads;
aligning a mask on the buffer layer, the mask having an opening therein to form jump metal lines therethrough; and
performing a sputtering process on the mask, thereby forming the jump metal lines on the buffer layer.

2. The method of claim 1, further comprising removing a bridge generated between the jump metal lines after the sputtering process.

3. The method of claim 2, wherein removing a bridge generated between the jump metal lines after the sputtering process comprises ion milling.

4. A method of manufacturing a center pad type integrated circuit chip, the method comprising:
forming a buffer layer on an integrated circuit chip;
forming a metal layer on the buffer layer;
aligning a mask over the metal layer, the mask having an opening to form jump metal lines; and
laser milling the metal layer through opening of the mask, thereby forming the jump metal lines on the buffer layer.
